(19) United States
(12) Patent Application Publication
(10) Pub. No.: US 2022/0186110 A1
(43) Pub. Date: Jun. 16, 2022

(54) OPTICAL FILM, BACKLIGHT MODULE AND MANUFACTURING METHOD OF OPTICAL FILM

(71) Applicant: NAN YA PLASTICS CORPORATION, TAIPEI (TW)

(72) Inventors: TE-CHAO LIAO, TAIPEI (TW); CHUN-CHE TSAO, TAIPEI (TW); Ren-Yu Liao, New Taipei City (TW)

(21) Appl. No.: 17/340,100

(22) Filed: Jun. 7, 2021

(30) Foreign Application Priority Data
Dec. 11, 2020 (TW) 109143755

(51) Int. Cl. C09K 11/02; C08J 5/18; C08L 35/02; F21V 8/00

(52) U.S. Cl. CPC C09K 11/02; C08J 5/18; B82Y 20/00; G02B 6/0026; C08L 35/02

(57) ABSTRACT

An optical film, a backlight module and a manufacturing method of the optical film are provided. The optical film is composed of a quantum dot gel layer. The quantum dot gel layer includes a first polymer and a plurality of quantum dots dispersed in the first polymer. The first polymer includes 1 to 5 wt % of photoinitiator, 3 to 20 wt % of scattering particles, 20 to 40 wt % of thiol compound, 5 to 30 wt % of monofunctional acrylic monomer, 20 to 40 wt % of multifunctional acrylic monomer, 1 to 5 wt % of organosilicon grafted oligomer, and 500 to 1500 ppm of inhibitor.

### CROSS-REFERENCE TO RELATED PATENT APPLICATION

This application claims the benefit of priority to Taiwan Patent Application No. 109143755, filed on Dec. 11, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an optical film, and more particularly to an optical film capable of being applied in a backlight module and an LED package.

### BACKGROUND OF THE DISCLOSURE

In recent years, with the development of display technology, people have higher requirements for the quality of displays. Quantum dots (QDs) have attracted wide attention from researchers due to their unique quantum confinement effects. Compared with conventional organic light-emitting materials, the luminous efficacy of the quantum dots has the advantages of having a narrow full width at half maximum (FWHM), small particles, no scattering loss, a spectrum that is adjustable with size, and a stable photochemical performance. In addition, the optical, electrical, and transmission properties of the quantum dots can be adjusted through a synthesis process. Such advantages have contributed to the importance of quantum dot technology, and polymer composite materials with quantum dots have been used in fields such as backlights and display devices in recent years.

However, the luminous efficiency of quantum dots is highly susceptible to oxygen, water vapor, etc. Conventionally, in optical film art, resin films are usually disposed on the front and back sides of a quantum dot film, or barrier films are further disposed on the quantum dot film, so as to improve an ability of the optical film to block water vapor and oxygen. However, costs and preparation time are increased due to the additional layer structure. Furthermore, a thickness of the final product cannot be reduced, so that the optical film cannot be applied to display devices other than televisions, and the application range of quantum dot technology on the display devices is limited.

Therefore, how to overcome the above-mentioned issues by improving the formulation of the quantum dot gel layer to omit the additional layer has become one of the important issues to be solved in this field.

### SUMMARY OF THE DISCLOSURE

In response to the above-referenced technical inadequacies, the present disclosure provides an optical film that is composed of only one single quantum dot gel layer, and has a thickness of only 30 to 50 μm.

In one aspect, the present disclosure provides an optical film composed of a quantum dot gel layer. More specifically, the quantum dot gel layer includes a first polymer and a plurality of quantum dots dispersed in the first polymer, and based on a total weight of the quantum dot gel layer being 100 weight percent, the first polymer including: 1 to 5 wt % of photoinitiator, 3 to 20 wt % of scattering particles, 20 to 50 wt % of thiol compound, 5 to 30 wt % of monofunctional acrylic monomer, 20 to 40 wt % of multifunctional acrylic monomer, 1 to 5 wt % of organosilicon grafted oligomer; and 500 to 1500 ppm of inhibitor.

In certain embodiments, the shielding layer further includes: a chemically treated surface, and the shielding layer being disposed on the quantum dot gel layer by the chemically treated surface.

In certain embodiments, the quantum dot gel layer has a first side and a second side, and the first side and the second side are exposed without a shielding layer being disposed thereon.

In certain embodiments, the thiol compound is selected from a group consisting of 2, 2′-(ethylenedioxy)diethyl mercaptan, 2,2′-thiodiethanethiol, trimethylolpropane tris(3-mercaptopropionate), poly(ethylene glycol) dithiol, pentaerythritol tetrakis (3-mercaptopropionate), ethylene glycol bis-mercaptoacetate, and ethyl 2-mercaptopropionate.

In certain embodiments, the monofunctional acrylic monomer is selected from a group consisting of tetrahydrofurfuryl methacrylate, stearyl acrylate, lauryl methacrylate, lauryl acrylate, isobornyl methacrylate, tridecyl acrylate, alkoxylated nonylphenol acrylate, tetraethylene glycol dimethacrylate, polyethylene glycol (600) dimethacrylate, tripropylene glycol diacrylate and ethoxylated (10) bisphenol A dimethacrylate.

In certain embodiments, the multifunctional acrylic monomer is selected from a group consisting of trimethylolpropane triacrylate, trimethylolpropane trimethacrylate, ethoxylated (20) trimethylolpropane triacrylate, and pentaerythritol triacrylate.

In certain embodiments, the organosilicon grafted oligomer is selected from the group consisting of silicone acrylate and silicone epoxy resin.

In certain embodiments, the inhibitor is selected from a group consisting of pyrogallol (PYR), hydroquinone, catechol, potassium iodide-iodine mixtures, hindered phenolics, aluminum/ammonium cupferronate salts (N-nitrosophenyl hydroxylamine ammonium salt/N-nitroso-N-phenylhydroxylamine aluminum salt), 3-propenylphenol triaryl phosphines, triaryl phosphines, triaryl phosphites, phosphonic acid, and a combination of an alkenyl-phenol and cupferronate salt.

In another aspect, the present disclosure provides a manufacturing method of optical film, comprising: dispersing a plurality of quantum dots in the first polymer to form a quantum dot gel layer; providing a shielding layer having a chemically treated surface, and based on a total weight of the quantum dot gel layer being 100 weight percent, the first polymer including: 1 to 5 wt % of photoinitiator, 3 to 20 wt % of scattering particles, 20 to 50 wt % of thiol compound, 5 to 30 wt % of monofunctional acrylic monomer, 20 to 40 wt % of multifunctional acrylic monomer, 1 to 5 wt % of organosilicon grafted oligomer; and 500 to 1500 ppm of inhibitor.

In certain embodiments, the manufacturing method of optical film further including: dispersing a plurality of quantum dots in the monofunctional acrylic monomer, and adding the inhibitor.

In certain embodiments, the manufacturing method of optical film further including: adding the thiol compound, adding the multifunctional acrylic monomer, and then adding the photoinitiator, scattering particles, and organosilicon grafted oligomer.

In yet another aspect, the present disclosure provides a backlight module, comprising: a light guide unit, at least one light emitting unit and an optical film; in which the optical film corresponds to the light entrance side and is disposed between the light guide unit and the at least one light emitting unit.

Specifically, the optical film is composed of a quantum dot gel layer that includes a first polymer and a plurality of quantum dots dispersed in the first polymer, in which the first polymer includes: 1 to 5 wt % of photoinitiator, 3 to 20 wt % of scattering particles, 20 to 50 wt % of thiol compound, 5 to 30 wt % of monofunctional acrylic monomer, 20 to 40 wt % of multifunctional acrylic monomer, 1 to 5 wt % of organosilicon grafted oligomer; and 500 to 1500 ppm of inhibitor.

Therefore, by virtue of “a quantum dot gel layer, including a first polymer and a plurality of quantum dots dispersed in the first polymer” and “the first polymer including: 1 to 5 wt % of photoinitiator, 3 to 20 wt % of scattering particles, 20 to 50 wt % of thiol compound, 5 to 30 wt % of monofunctional acrylic monomer, 20 to 40 wt % of multifunctional acrylic monomer, 1 to 5 wt % of organosilicon grafted oligomer; and 500 to 1500 ppm of inhibitor”, the present disclosure provides a quantum dot gel layer that can omit one side of the shielding layer, or even both sides of the shielding layers. In other words, the optical film requires only the quantum dot gel layer to maintain high water vapor and oxygen resistance.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a sectional view of an optical film according to an embodiment of the present disclosure;

FIG. 2 is a flowchart of a manufacturing method of the optical film according to an embodiment of the present disclosure;

FIG. 3 is a flowchart of the manufacturing method of the optical film according to another embodiment of the present disclosure; and

FIG. 4 is a sectional view of a backlight module according to an embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

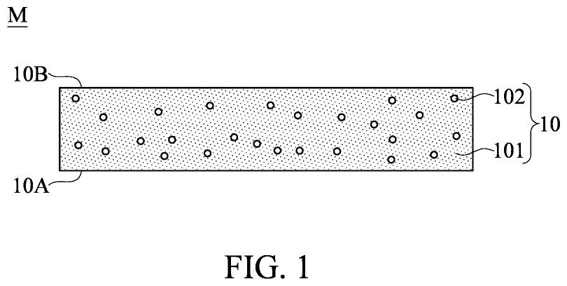

Referring to FIG. 1, a first embodiment of the present disclosure provides an optical film M composed of a quantum dot gel layer 10. More specifically, the quantum dot gel layer 10 includes a first polymer 101 and a plurality of quantum dots 102 dispersed in the first polymer 101. Further, the quantum dot gel layer 10 has a first side 10A and a second side 10B, and both the first side 10A and the second side 10B are exposed and not covered. In detail, the optical film M, i.e., the quantum dot gel layer 10 has a thickness of about 30 to 50 μm.

Furthermore, the detailed description of composition and ratio of the quantum dot gel layer is as follows: the quantum dot gel layer includes a first polymer and a plurality of quantum dots dispersed in the first polymer, in detail, the quantum dot gel layer includes 1 to 5 wt % of photoinitiator, 3 to 20 wt % of scattering particles, 20 to 50 wt % of thiol compound, 5 to 30 wt % of monofunctional acrylic monomer, 20 to 40 wt % of multifunctional acrylic monomer, 1 to 5 wt % of organosilicon grafted oligomer; and 500 to 1500 ppm of inhibitor. It should be noted that based on a total weight of the quantum dot gel layer being 100 weight percent, the total mixed weight of photoinitiator, scattering particles, thiol compound, monofunctional acrylic monomer, multifunctional acrylic monomer and organo silicon grafted oligomer is 100% by weight, and then add 500 to 1500 ppm of inhibitor.

The photoinitiator is selected from a group consisting of 1-hydroxycyclohexyl phenyl ketone, benzoyl isopropanol, tribromomethyl benzene sulfide and diphenyl (2, 4, 6-trimethylbenzoyl) phosphine oxide. The scattering particle is a surface-treated acrylic or silicon dioxide or polystyrene beads, and has a particle size from 0.5 to 20 μm. However, it is difficult to cure when the content of the photoinitiator is less than 1 wt %, and it would affect the volatility of the overall properties of the gel layer when the content of the photoinitiator is more than 5 wt %.

The scattering particle is surface-treated microbeads and has particle size 0.5 to 10 μm, in which the material of the microbeads can be acrylic, silicon dioxide, germanium dioxide, titanium dioxide, zirconium dioxide, aluminum oxide or polystyrene. The refractive index of the scattering particle is about 1.39 to 1.45. The scattering particles provide better light scattering for the quantum dots, so that the light passing through the quantum dot gel layer would be more uniform. When the scattering particles content is less than 3 wt %, the haze will be insufficient, and when the content exceeds 20 wt %, the haze will be too much, which results in the overall material resin content insufficiency, and affects dispersibility and increases processing difficulty.

Specifically, the thiol compound is selected from a group consisting of 2, 2′-(ethylenedioxy)diethyl mercaptan, 2, 2′-thiodiethanethiol, trimethylolpropane tris(3-mercaptopropionate), poly(ethylene glycol) dithiol, pentaerythritol tetrakis (3-mercaptopropionate), ethylene glycol bis-mercaptoacetate, and ethyl 2-mercaptopropionate. The thiol compound is a non-aromatic compound containing a sulfhydryl functional group (—SH), which provides a functional group with better binding properties to the quantum dot, so that the quantum dot has better dispersibility. The content of the thiol compound is higher in comparison to that of the conventional art so as to have a higher degree of polymerization. However, the above-mentioned effect is not present when the content of the thiol compound is less than 20 wt %, and the gel layer becomes too soft and easily bent when the content of the thiol compound exceeds 50 wt %.

The monofunctional acrylic monomer is selected from a group consisting of tetrahydrofurfuryl methacrylate, stearyl acrylate, lauryl methacrylate, lauryl acrylate, isobornyl methacrylate, tridecyl acrylate, alkoxylated nonylphenol acrylate, tetraethylene glycol dimethacrylate, polyethylene glycol (600) dimethacrylate, tripropylene glycol diacrylate and ethoxylated (10) bisphenol A dimethacrylate. When the content of the monofunctional acrylic monomer is too low, the quantum dots have poor dispersibility, and when the content is too high, it leads to low polymerization efficiency and poor weather resistance.

The multifunctional acrylic monomer is selected from a group consisting of trimethylolpropane triacrylate, trimethylolpropane trimethacrylate, ethoxylated (20) trimethylolpropane triacrylate, and pentaerythritol triacrylate. When the amount of the multifunctional acrylic monomer is excessive, the gel layer may become too brittle and prone to breakage.

The organosilicon grafted oligomer is selected from the group consisting of silicone acrylate and silicone epoxy resin. The organosilicon grafted oligomer can increase the weather resistance of the polymer, and further improve the mechanical strength of the polymer. Generally, in the conventional art, if a shielding layer is omitted in the optical film, it will not only reduce the effect of water vapor and oxygen resistance, but also cause the defect of insufficient mechanical strength. Therefore, in the present disclosure, 1 to 5 wt % of the organosilicon grafted oligomer can improve the mechanical strength of the quantum dot gel layer. When the amount of the organo silicon grafted oligomer is greater than 1 to 5 wt %, the dispersibility and processability is affected, and the cost is increased.

The inhibitor is selected from a group consisting of pyrogallol (PYR), hydroquinone, catechol, potassium iodide-iodine mixtures, hindered phenolics, aluminum/ammonium cupferronate salts (N-nitrosophenyl hydroxylamine ammonium salt/N-nitroso-N-phenylhydroxylamine aluminum salt), 3-propenylphenol triaryl phosphines, triaryl phosphines, triaryl phosphites, phosphonic acid, and a combination of an alkenyl-phenol and cupferronate salt. The inhibitor can effectively slow down the reaction rate and avoid the mutual influence of the formula in the composition. For example, the thiol compound and multifunctional acrylic monomer are easy to self-react at room temperature. The addition of inhibitor in the manufacturing method provides better processability and more stable preservation. However, when the amount of the inhibitor is less than 500 ppm, the suppression effect cannot be achieved, and when the amount of the inhibitor exceeds 1500 ppm, the photocuring efficiency is affected.

Further, a plurality of quantum dots (QDs) includes red quantum dots, green quantum dots, blue quantum dots and combination thereof. For example, it may be a combination of red quantum dots and green quantum dots. These quantum dots have different or the same particle size. In addition, each quantum dot may include a core and a shell, and the shell covers the core. In one or more embodiments, the material of the core/shell of the quantum dots may include cadmium selenide (CdSe)/zinc sulfide (ZnS), indium phosphide (InP)/zinc sulfide (ZnS), lead selenide (PbSe)/lead sulfide (PbS), cadmium selenide (CdSe)/cadmium sulfide (CdS), cadmium telluride (CdTe)/cadmium sulfide (CdS) or cadmium telluride (CdTe)/zinc sulfide (ZnS), but the embodiments are not meant to limit the scope of the present disclosure.

Furthermore, both the core and the shell of the quantum dots can be composite materials in Group II-VI, Group II-V, Group III-VI, Group III-V, Group IV-VI, Group II-IV-VI or Group II-IV-V, where the term “group” refers to element group of the periodic table.

Specifically, the material of the core can be zinc sulfide (ZnS), zinc selenide (ZnSe), zinc telluride (ZnTe), cadmium sulfide (CdS), cadmium selenide (CdSe), cadmium telluride (CdTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), gallium selenide (GaSe), indium nitride (InN), indium phosphide (InP), indium arsenide (InAs), indium antimonide (InSb), thallium nitride (TlN), thallium phosphide (TlP), thallium arsenide (TlAs), thallium antimonide (TlSb), lead sulfide (PbS), lead selenide (PbSe), lead telluride (PbTe) or any combination of the above.

The material of the shell can be zinc oxide (ZnO), zinc sulfide (ZnS), zinc selenide (ZnSe), zinc telluride (ZnTe), cadmium oxide (CdO), cadmium sulfide (CdS), cadmium selenide (CdSe), cadmium telluride (CdTe), magnesium oxide (MgO), magnesium sulfide (MgS), magnesium selenide (MgSe), magnesium telluride (MgTe), mercury oxide (HgO), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), indium nitride (InN), indium phosphide (InP), indium arsenide (InAs), indium antimonide (InSb), thallium nitride (TlN), thallium phosphide (TlP), thallium arsenide (TlAs), thallium antimonide (TlSb), lead sulfide (PbS), lead selenide (PbSe), lead telluride (PbTe) or any combination of the above.

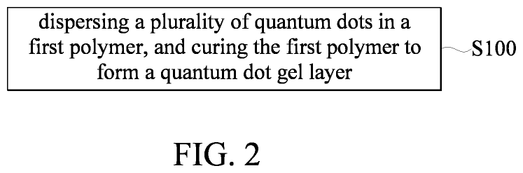

Referring to FIG. 2, the present disclosure further provides a manufacturing method of the optical film, including: S100: dispersing a plurality of quantum dots in the first polymer, and curing the first polymer to form a quantum dot gel layer.

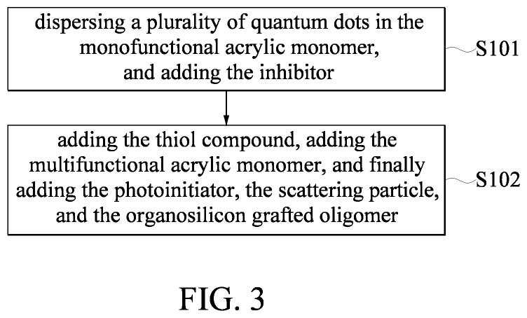

The composition of the first polymer and quantum dots are as described above. More specifically, as shown in FIG. 3, the dispersing step of S100 includes: S101: firstly, dispersing a plurality of quantum dots in the monofunctional acrylic monomer, adding the inhibitor, and S102: adding the thiol compound, then further adding the multifunctional acrylic monomer, and finally adding the photoinitiator, scattering particles, and organosilicon grafted oligomer.

In other words, the step of dispersing a plurality of quantum dots in the first polymer is not dispersing the plurality of quantum dots in the final mixture of the first polymer, but dispersing the plurality of quantum dots in certain compositions in order, then adding other compositions and fully mixing it, and then proceeding to the curing step.

In addition to the foregoing steps, the manufacturing method of optical film of the present disclosure further includes: performing a cutting process to cut the optical film into required size; and performing a winding process to wind the rest of optical film into a roll for use or storage.

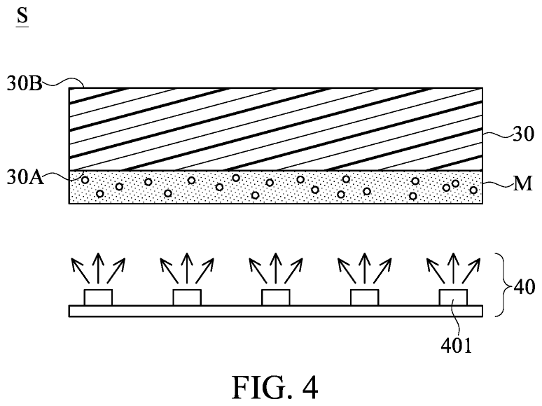

Referring to FIG. 4, the present disclosure further provides a backlight module S, including: a light guide unit 30, at least one light emitting unit 40 and an optical film M. The light guide unit 30 has a light incident side 30A, and the at least one light emitting unit 40 is corresponding to the light incident side 30A, and has a plurality of light emitting units. The optical film M is opposite to the light incident side 30A, and the optical film M is located between the light guide unit 30 and the at least one light emitting unit 40. In detail, the light guide unit 30 has a light incident side 30A and a light emitting side 30B, the optical film M is disposed on the light incident side 30A, more specifically, the optical light unit M is the above-mentioned optical film of the present disclosure. However, the aforementioned description is merely an example and is not meant to limit the scope of the present disclosure.

### EMBODIMENTS

As shown in Table 1, the quantum dot gel layer of embodiment 1, embodiment 2, and comparative embodiment 1 are manufactured according to the following formula and ratio, and the quantum dot gel layer undergoes the following product property tests. In detail, the following ratio is based on a total weight of the quantum dot gel layer being 100 weight percent, in which the total weight of the photoinitiator, the scattering particles, the thiol compound, the monofunctional acrylic monomer, the multifunctional acrylic monomer and the organosilicon grafted oligomer is 100 weight percent, and the inhibitor is then added.

Specifically, the detailed steps are firstly dispersing a plurality of quantum dots in the monofunctional acrylic monomer to form a quantum dots-monofunctional acrylic solution, followed by adding the inhibitor to the quantum dots-monofunctional acrylic solution and mixing evenly, then adding the thiol compound, and the multifunctional acrylic monomer, finally adding the photoinitiator, scattering particles and organosilicon grafted oligomer, mix uniformly to obtain the material of the quantum dot layer.

Coat the aforementioned material of the quantum dot layer on a carrier layer, and then drying treatment to obtain the quantum dot layer.

TABLE 1

| | | | Comparative |
|---|---|---|---|
| Formula | Embodiment 1 | Embodiment 2 | embodiment 1 |
| Photoinitiator | 3 wt % | 3 wt % | 3 wt % |
| Scattering particles | 10 wt % | 10 wt % | 10 wt % |
| Thiol compound | 20 wt % | 20 wt % | 0 wt % |
| Monofunctional | 25 wt % | 25 wt % | 50 wt % |
| acrylic monomer | | | |
| Multifunctional | 35 wt % | 35 wt % | 35 wt % |
| acrylic monomer | | | |
| Organosilicon | 5 wt % | 5 wt % | 0 wt % |
| grafted oligomer | | | |
| Quantum dot | 2 wt % | 2 wt % | 2 wt % |
| particles | | | |
| Inhibitor | 1000 ppm | 1000 ppm | 0 |
| Thickness | 30 μm | 50 μm | 30 μm |
| Water | under 65° C., | under 65° C., | under 65° C., |
| vapor and | and 95% | and 95% | and 95% |
| oxygen | relative | relative | relative |
| resistance | humidity, | humidity, | humidity, |
| | 0% of | 0% of | 12% of |
| | brightness | brightness | brightness |
| | lost after | lost after | lost after |
| | 1000 hours | 1000 hours | 1000 hours |
| | of running x, | of running x, | of running x, |
| | y chromaticity | y chromaticity | y chromaticity |
| | shift 0.0020 | shift 0.0020 | shift 0.0150 |
| Light penetration | 92% | 90% | 87% |
| Refractive index | 1.55 | 1.55 | 1.49 |
| Mechanical | foldable | foldable | non- foldable |
| properties | | | Maximum |
| | | | bending |
| | | | angle <70 |
| Contractility | 29 ppm/° C. | 29 ppm/° C. | 34 ppm/° C. |
| Brightness | 650 Cd/m² | 695 Cd/m² | 510 Cd/m² |

### Beneficial Effects of the Embodiments

In conclusion, by virtue of “a quantum dot gel layer, including a first polymer and a plurality of quantum dots dispersed in the first polymer” and “the first polymer including: 1 to 5 wt % of photoinitiator, 3 to 20 wt % of scattering particles, 20 to 50 wt % of thiol compound, 5 to 30 wt % of monofunctional acrylic monomer, 20 to 40 wt % of multifunctional acrylic monomer, 1 to 5 wt % of organosilicon grafted oligomer; and 500 to 1500 ppm of inhibitor”, the present disclosure provides an optical film that can omit the shielding layer(s), in other words, the optical film only requires one quantum dot gel layer to have excellent water vapor and oxygen resistance, and maintains moderate mechanical strength and shrinkage.

More specifically, the thiol compound is a non-aromatic compound of a sulfhydryl functional group (—SH) with better binding properties to the quantum dot, so that the quantum dot has better dispersibility. Further, the amount of the thiol compound is higher than that of the conventional art, so as to have a higher degree of polymerization.

Moreover, comparing with the conventional optical film, eliminating the shielding layer not only reduces the water vapor and oxygen resistance, but also cures the defect of insufficient mechanical strength. Therefore, the organosilicon grafted oligomer of the present disclosure selected from the group consisting of silicone acrylate and silicone epoxy resin can increase the mechanical strength of a polymer gel layer, effectively omit the shielding layer but maintain the same optical film characteristics, and further reduce the thickness of the optical film to about 30 to 50 μm. Therefore, the optical film has better optical properties and is suitable for backlight modules using blue light to be applied to thin mobile phone products.

In addition, the formula of the present disclosure noted the problem of mutual influence when mixing the composition. After various experiments, the present disclosure has selected a group of specific inhibitors, which can effectively slow down the reaction rate and avoid self-reaction between the thiol compound and the multifunctional acrylic monomer at room temperature, further providing better processability and stable storage.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An optical film, composed of a quantum dot gel layer including a first polymer and a plurality of quantum dots dispersed in the first polymer;
wherein, based on a total weight of the quantum dot gel layer being 100 weight percent, the first polymer includes:
1 to 5 wt % of photoinitiator;
3 to 20 wt % of scattering particles;
20 to 50 wt % of thiol compound;
5 to 30 wt % of monofunctional acrylic monomer;
20 to 40 wt % of multifunctional acrylic monomer;
1 to 5 wt % of organosilicon-grafted oligomer; and
500 to 1500 ppm of inhibitor.

2. The optical film according to claim 1, wherein the quantum dot gel layer has a first side and a second side, and the first side and the second side are exposed without a shielding layer being disposed thereon.

3. The optical film according to claim 1, wherein the thiol compound is selected from a group consisting of 2, 2′-(ethylenedioxy)diethyl mercaptan, 2,2′-thiodiethanethiol, trimethylolpropane tris(3-mercaptopropionate), poly(ethylene glycol) dithiol, pentaerythritol tetrakis (3-mercaptopropionate), ethylene glycol bis-mercaptoacetate, and ethyl 2-mercaptopropionate.

4. The optical film according to claim 1, wherein the monofunctional acrylic monomer is selected from a group consisting of tetrahydrofurfuryl methacrylate, stearyl acrylate, lauryl methacrylate, lauryl acrylate, isobornyl methacrylate, tridecyl acrylate, alkoxylated nonylphenol acrylate, tetraethylene glycol dimethacrylate, polyethylene glycol (600) dimethacrylate, tripropylene glycol diacrylate and ethoxylated (10) bisphenol A dimethacrylate; and the multifunctional acrylic monomer is selected from a group consisting of trimethylolpropane triacrylate, trimethylolpropane trimethacrylate, ethoxylated (20) trimethylolpropane triacrylate, and pentaerythritol triacrylate.

5. The optical film according to claim 1, wherein the organosilicon grafted oligomer is selected from the group consisting of silicone acrylate and silicone epoxy resin.

6. The optical film according to claim 1, wherein the inhibitor is selected from a group consisting of pyrogallol (PYR), hydroquinone, catechol, potassium iodide-iodine mixtures, hindered phenolics, aluminum/ammonium cupferronate salts (N-nitrosophenyl hydroxylamine ammonium salt/N-nitroso-N-phenylhydroxylamine aluminum salt), 3-propenylphenol triaryl phosphines, triaryl phosphines, triaryl phosphites, phosphonic acid, and a combination of an alkenyl-phenol and cupferronate salt.

7. A manufacturing method of an optical film, comprising:
dispersing a plurality of quantum dots in a first polymer to form a quantum dot gel layer;
wherein, based on a total weight of the quantum dot gel layer being 100 weight percent, the first polymer includes:
1 to 5 wt % of photoinitiator;
3 to 20 wt % of scattering particles;
20 to 50 wt % of thiol compound;
5 to 30 wt % of monofunctional acrylic monomer;
20 to 40 wt % of multifunctional acrylic monomer;
1 to 5 wt % of organosilicon grafted oligomer; and
500 to 1500 ppm of inhibitor.

8. The manufacturing method according to claim 7, further including: dispersing the plurality of quantum dots in the monofunctional acrylic monomer, and then adding the inhibitor.

9. The manufacturing method according to claim 8, after adding the inhibitor, further including: adding the thiol compound, adding the multifunctional acrylic monomer, and then adding the photoinitiator, scattering particles, and organosilicon grafted oligomer.

10. A backlight module, comprising:
a light guide unit having a light entrance side;
at least one light emitting unit corresponding to the light entrance side; and
an optical film corresponding to the light entrance side and disposed between the light guide unit and the at least one light emitting unit, wherein the optical film includes a quantum dot gel layer including a first polymer and a plurality of quantum dots dispersed in the first polymer;
wherein, based on a total weight of the quantum dot gel layer being 100 weight percent, the first polymer includes:
1 to 5 wt % of photoinitiator;
3 to 20 wt % of scattering particles;
20 to 50 wt % of thiol compound;
5 to 30 wt % of monofunctional acrylic monomer;
20 to 40 wt % of multifunctional acrylic monomer;
1 to 5 wt % of organosilicon grafted oligomer; and
500 to 1500 ppm of inhibitor.
